(19) United States
(12) Patent Application Publication
(10) Pub. No.: US 2025/0321291 A1
(43) Pub. Date: Oct. 16, 2025

(54) TESTING A POWER SUPPLY

(71) Applicant: Teradyne, Inc., North Reading, MA (US)

(72) Inventor: Tushar Gohel, Winchester, MA (US)

(73) Assignee: Teradyne, Inc., North Reading, MA (US)

(21) Appl. No.: 18/631,623

(22) Filed: Apr. 10, 2024

(51) Int. Cl. G01R 31/40

(52) U.S. Cl. CPC G01R 31/40

(57) ABSTRACT

An example system is for testing a switched-mode power supply that includes a device associated with a pulse-width modulated (PWM) signal. The system includes a conductive structure wirelessly coupled to the device such that a change in electrical energy in the device produces a transient response on the conductive structure, and circuitry configured to perform operations that include: converting the transient response into an electrical signal, and generating, based on the electrical signal, a local PWM signal that corresponds to the PWM signal used in the switched-mode power supply.

### TECHNICAL FIELD

This specification describes example implementations of techniques for testing a power supply, such as a switched-mode power supply.

### BACKGROUND

A test system is configured to test the operation of a device. A device tested by a test system is referred to as a device under test (DUT). An example of a type of DUT that may be tested using a test system includes a power supply. An example power supply is a device that provides power, including current and voltage, to a load. The load may be any type of electronic device.

### SUMMARY

An example system is for testing a switched-mode power supply that includes a device associated with a pulse-width modulated (PWM) signal. The system includes a conductive structure wirelessly coupled to the device such that a change in electrical energy in the device produces a transient response on the conductive structure, and circuitry configured to perform operations that include: converting the transient response into an electrical signal, and generating, based on the electrical signal, a local PWM signal that corresponds to the PWM signal used in the switched-mode power supply. The system may include one or more of the following features, either alone or in combination.

The electrical signal may include a differential signal. The system may include devices configured to determine one or more attributes of the local PWM signal. The one or more attributes may include one or more of a relative average voltage of the local PWM signal, a peak-to-peak voltage or amplitude of the local PWM signal, an average duty cycle of the local PWM signal, power of the PWM signal, or a frequency of the local PWM signal.

The circuitry may include a filter circuit having hysteresis. The local PWM signal may be based on an output of the filter circuit. The conductive structure may include a conductive plate at least partly wrapped in an insulating material. The local PWM signal may include a reconstruction of the PWM signal used in the switched-mode power supply. The local PWM signal may have a substantially same frequency and substantially same pulse widths as the PWM signal used in the switched-mode power supply.

The circuitry may include: an amplifier circuit configured to receive the electrical signal and to produce an amplified electrical signal based on the received electrical signal; a filter circuit that includes a charge storage element configured to capture signal transient edges and to remove at least some noise from the amplified electrical signal to produce an intermediate (e.g., filtered) signal having rising and falling edges corresponding to rising and falling edges of the PWM signal; and a comparator circuit configured to compare the intermediate signal to a predefined reference voltage and to output the local PWM signal.

The circuitry may include a peak detector circuit configured to receive the local PWM signal and to determine a value of a peak-to-peak voltage or amplitude of the local PWM signal. The circuitry may include a filter circuit configured to receive the local PWM signal and to determine a value of a relative average voltage of the local PWM signal. An average duty cycle of the PWM signal used in the switched-mode power supply may be based on the peak-to-peak voltage or amplitude of the local PWM signal and the relative average voltage of the local PWM signal.

The circuitry may include first circuitry configured to perform at least the converting operations and second circuitry configured to perform at least the generating operations. The second circuitry may be remote from the first circuitry. The system may include two or more conductors between the first circuitry and the second circuitry.

The first circuitry may include a converter circuit configured to convert a single-ended signal that is based on the transient response into a differential signal for output to the two or more conductors. The second circuitry may include multiplexer circuitry. The multiplexer circuitry nay be configured to receive the electrical signal over a test channel and to select the electrical signal based on a signal corresponding to the switched-mode power supply.

The system may be configured to test multiple switched-mode power supplies each of which include a respective device associated with a respective PWM signal. The system may include multiple instances of the conductive structure each wirelessly coupled to respective devices of different respective switched-mode power supplies, and multiple instances of the first circuitry each configured to convert a transient response from each respective instance of the conductive structure to a respective electrical signal. The second circuitry may include a pair of multiplexers. The pair of multiplexers may be configured to receive a device of each respective electrical signal over a respective test channel and to select a received device of the electrical signal to process in the second circuitry based on a signal corresponding to the switched-mode power supply. The system may include multiple instances of the second circuitry that are remote from corresponding instance of the first circuitry and that are each configured to determine, based on a respective electrical signal, values corresponding to one or more attributes of a respective local PWM signal.

Each instance of the second circuitry may include a pair of multiplexers. Each pair of multiplexers may be configured to receive respective electrical signals over respective test channels and to select received respective electrical signals to process in the each instance of the second circuitry. The local PWM signal may be an inverted version of the original PWM signal.

An example method is for testing a switched-mode power supply that include a device associated with a pulse-width modulated (PWM) signal. The method includes receiving, at a conductive structure wirelessly coupled to the device, a transient response that is based on a change in electrical energy in the device; converting the transient response into an electrical signal; and generating a local PWM signal that corresponds to the PWM signal used in the switched-mode power supply based on the electrical signal. The method may include one or more of the following features, either alone or in combination.

The method may include determining values corresponding to one or more attributes of the local PWM signal. The method may include determining a value of a peak-to-peak voltage or amplitude of the local PWM signal. The method may include determining a value of a relative average voltage of the local PWM signal. The method may include determining a value of an average duty cycle of the local PWM signal. The method may include determining a value of a frequency of the local PWM signal. The one or more attributes may include one or more of a relative average voltage of the local PWM signal, a peak-to-peak voltage or amplitude of the local PWM signal, an average duty cycle of the local PWM signal, or a frequency of the local PWM signal.

Generating the local PWM signal may include producing an amplified electrical signal based on the received electrical signal and removing at least some noise from the amplified electrical signal to produce an intermediate (e.g., filtered) electrical signal. The local PWM signal may be generated based on the intermediate electrical signal. The local PWM signal may have a substantially same frequency and duty cycle as the PWM signal used in the switched-mode power supply. The converting operations performed by the method may be performed by first circuitry; the generating operations performed by the method may be performed by second circuitry; and the first circuitry may be remote from the second circuitry.

Any two or more of the features described in this specification, including in this summary section, may be combined to form implementations not specifically described in this specification.

At least part of the devices, systems, circuitry and processes described in this specification may be configured or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, circuitry, and processes described in this specification may be configured or controlled using a computing system comprised of one or more processing devices and memory storing instructions that are executable by the one or more processing devices to perform various control operations. The devices, systems, circuitry, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a combined circuit and block diagram of an example of a power supply to be tested and an example sensor card used for testing.

FIG. 2 is a block diagram of an example system for testing devices, such as power supplies.

FIG. 3 is a block diagram of an example implementation of the sensor card shown in FIGS. 1 and 2.

FIG. 4 is a diagram showing example circuitry that may be on the sensor card.

FIG. 5 is a diagram showing example circuitry that may be on a processing card that is in communication with the sensor card.

FIG. 6 is a diagram showing an example pulse-width modulated (PWM) signal used in a device under test, such as a power supply, a reconstructed version thereof, and intermediate (e.g., filtered) signals used to produce the reconstructed version.

FIG. 7 is a block diagram of another example implementation the processing card of FIG. 5.

FIG. 8 is a block diagram of another example implementation of the processing card of FIG. 5.

FIG. 9 is a circuit diagram showing example circuitry contained in a processing card containing multiplexers.

FIG. 10 is a flowchart showing example operations included in a process for reconstructing a PWM signal and determining attributes thereof.

FIG. 11 is a block diagram of example test equipment with which the example circuitry and processes described herein may be implemented.

FIG. 12 is a diagram showing examples of an amplified signal, an intermediate (e.g., filtered) signal, and an reconstructed PWM signal.

Like reference numerals in different figures indicate like elements.

### DETAILED DESCRIPTION

Described herein are example of systems and processes for testing devices, such as power supplies, having components that are controlled using pulse-width modulated (PWM) signals. Although the examples presented herein focus on power supplies, the systems and processes may be used to test any type of device.

An example of a type of power supply that the systems processes may test includes a switched-mode power supply (SMPS). A SMPS is a power supply that is configured to switch current to a load on and off, thereby producing an output direct current (DC) voltage to the load. An example SMPS includes, among other things, a connection to a DC or alternating current (AC) power source, one or more switches, and one or more energy storage devices. The switch(s) may be implemented using transistors that open and close at a relatively high frequency, such as in a range of hundred(s) of kilohertz (kHz) to several megahertz (MHZ)—for example in a range of 100 kHz to 1 MHz. The energy storage device(s) may be implemented using one or more inductors (L) and/or one or more capacitors (C).

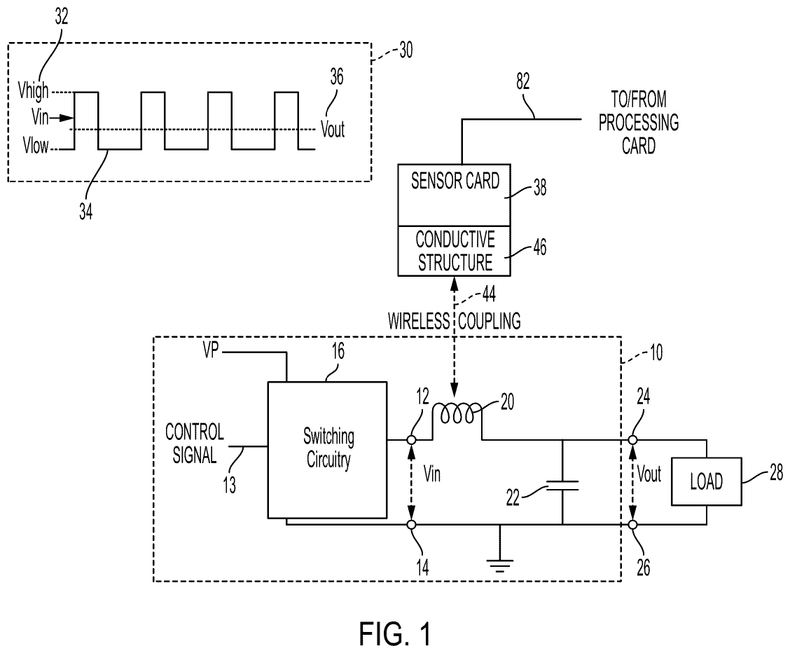

FIG. 1 shows an example circuit configuration used in an example SMPS 10 that is configured to operate as a step-down, or buck, power converter. A step-down power converter produces an output voltage that has a magnitude that is less than a magnitude of the voltage input to the power converter. Other example configurations (not shown) of SMPSs may operate as a step-up, or boost, power converter. A step-up power converter produces an output voltage that has a magnitude that is greater than a magnitude of the voltage input to the power converter. Other example configurations (not shown) of SMPSs may neither step-up nor step-down power.

SMPS 10 of FIG. 1 is presented as an example of an SMPS that the systems and processes described herein may test. The systems and processes are not limited to testing SMPSs having the configuration of FIG. 1, and may be used to test any type of SMPS, power supply, or device that operates using PWM signals.

SMPS 10 includes input terminals 12, 14 for connection to a power source, Vin/VP, such as an AC or DC power source. SMPS 10 also includes a switching circuitry 16, which may be implemented using one or more transistors such as a bipolar junction transistor (BJT) or metal-oxide-semiconductor field-effect transistor (MOSFET) and, in some examples, one or more diodes. SMPS 10 also includes an inductor 20, a capacitor 22, and output terminals 24, 26 to provide an output voltage (Vout) to a load 28. Load 28 may be any type of electronic device.

Switching circuitry 16 may be driven by an AC or DC control signal 13 that contains a pulse-width modulated (PWM) signal 30, which may be a square wave in some examples. When switching circuitry 16 is driven to conduction, e.g., in response to high voltage 32 (V_{high}) of PWM signal 30, current from the power source passes through switching circuitry 16 and inductor 20 to load 28. This current also charges capacitor 22. Inductor 20 opposes this current and produces a magnetic field. When switching circuitry 16 opens, e.g., a transistor stops conducting in response to a low voltage 34 (Vlow) of PWM signal 30, voltage/current input from the power source to the SMPS ends. As a result, the magnetic field produced by inductor 20 collapses. This configuration allows current from inductor 20 to flow through load 28. At the same time, capacitor 22 discharges causing current to flow from capacitor 22 through load 28. In this example, the foregoing operations produce a value (e.g., a magnitude) of Vout 36 that is between high voltage 32 and low voltage 34 of PWM signal 30. SMPS 10 may regulate this value of the output voltage, Vout, 36 by varying the ratio of on-time (V_{high}) to off-time (Vlow) of PWM signal 30. This ratio of the on-time to the off-time of PWM signal 30 is the duty cycle of PWM signal 30.

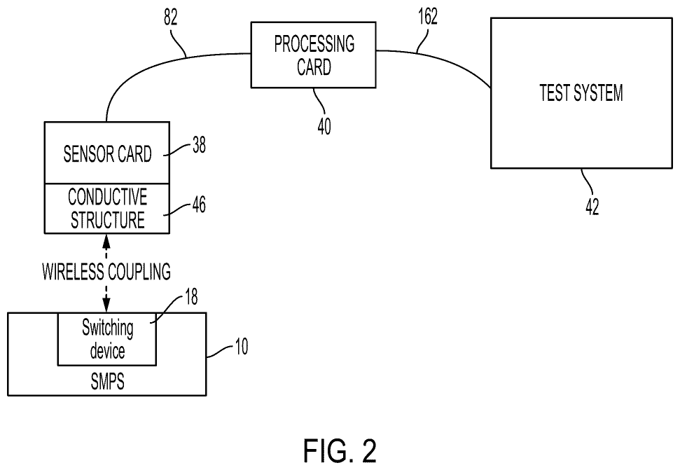

Referring also to FIG. 2, examples of the systems described herein include (A) circuitry, such as (i) a sensor card 38 containing first circuitry and (ii) a processing card 40 containing second circuitry, and (B) a test system 42, such as automatic test equipment (ATE). Referring also to the example configuration of FIG. 1, sensor card 38 is movable to within a predefined physical distance 44 of an electronic device of a DUT (e.g., SMPS 10), where the electronic device of the DUT is associated with a PWM signal. An electronic device associated with a PWM signal includes any type of passive device (e.g., an energy storage device such as inductor 20 or a capacitor) or any type of active device (e.g., a transistor) that is controlled by, or affected by, switching actions such as those caused by a PWM signal. Herein, such electronic devices are referred to as “switching devices”. An example of the predefined physical distance may be between 0.1 millimeters (mm) and 1 mm; however, the systems described herein are not limited to this range of distances. This physical proximity enables wireless coupling between a conductive structure 46 on sensor card and the switching device, as described below. Distance between the switching device and the sensor card affect the magnitude of the coupling. The closer the proximity is, the greater the coupling is. Adjusting this distance can be used as a way to optimize the coupling to maximize circuit performance. In some implementations, an insulator between the conductive structure 46 and the switching device may allow for direct contact between the conductive structure and the switching device through the insulator. For example, an insulator may cover the conductive structure or the switching device or both.

Sensor card 38 is electrically connected to processing card 40 via one or more conductors, which may be implemented as coaxial cables, shielded twisted pair wires, or other appropriate wiring. Other types of wires can be used to maintain signal fidelity and to limit crosstalk. In this example, sensor card 38 is remote from processing card 40. For example, sensor card 38 may be 30 centimeters (cm) to 90 cm away from processing card 40; however, the systems described herein are not limited to this range of distances. Processing card 40 may be inside test system 42 or it may be external to test system 42. In cases, where processing card 40 is external to the test system, processing card 40 may in wired or wireless communication with test system 42.

As noted, sensor card 38 includes a conductive structure 46 that is configured to wirelessly couple—for example, capacitively couple—to a switching device in a power supply such as inductor 20. As noted above, the conductive structure may be insulated allowing for direct contact in some implementations. This wireless coupling enables a change in the electrical energy in the switching device to produce a transient response on conductive structure 46. In the example of FIG. 1, PWM signal 30 causes switching circuitry 16 to open and close, thereby causing a change in electrical energy in inductor 20, which results in a transient response on conductive structure 46. The first circuitry in sensor card 38 converts this transient response into an electrical signal; such as a differential signal. This electrical signal is then output over the one or more conductors to processing card 40. The second circuitry in processing card 40 generates, based on the electrical signal, a local PWM signal. In this example, the local PWM signal corresponds to PWM signal 30 that controls switching. In some examples, the local PWM signal has some of same or substantially the same attributes as PWM signal 30, such as its duty cycle and frequency, but may have substantially or insubstantially different peak and relative average voltages. In some examples, the local PWM signal has the same or substantially the same peak-to-peak voltage or amplitude or relative average voltage as PWM signal 30, where the peak-to-peak voltage or amplitude refers to the high voltage (e.g., 32) of the PWM signal minus the low voltage (e.g., 34) of the PWM signal and where the relative average voltage refers to the average voltage of the PWM signal minus the low voltage (e.g., 34). In some examples, the local PWM signal may be an exact or substantial reconstruction of PWM signal 30. In some examples, an attribute of the local PWM signal is substantially the same as an attribute of the PWM signal used in a DUT such as SMPS 10 if the deviation between the two attributes is less than 5%, less than 4%, less than 3%, less than 2%, or less than 1%. In some examples, the local PWM signal may be an inverted version of the original PWM signal.

In this example, the second circuitry in the processing card and/or a test system in communication with the processing card may be configured to determine one or more attributes of the local PWM signal. Examples of such attributes include, but are not limited to, one or more of a relative average voltage of the local PWM signal, a peak-to-peak voltage or amplitude of the local PWM signal, an average duty cycle of the local PWM signal, a power of the local PWM signal, or a frequency of the local PWM signal. In some implementations, the local PWM signal may be provided to test system 42, which may determine all or some of the one or more attributes of the local PWM signal. For example, in such implementations, the second circuitry determines the local PWM signal and outputs the local PWM signal to the test system without determining any of the attributes.

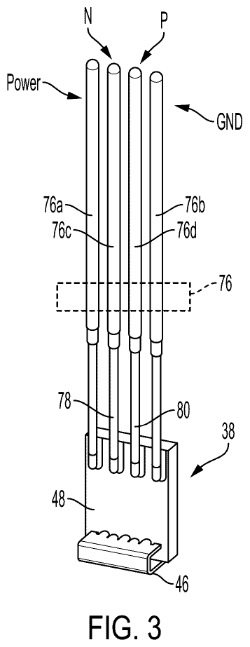

FIG. 3 is a block diagram showing an example implementation of sensor card 38. In this example, sensor card 38 includes a conductive structure 46. Conductive structure 46 may be an electrically conductive plate or an apparatus having at least one flat or substantially flat surface. Conductive structure may be made of copper, aluminum, or any other electrically-conductive metal or other material. All or part of conductive structure 46 may be covered—for example, wrapped—in an insulating material such as polyimide or plastic. In some implementations, only the portion of conductive structure 46 configured to face a DUT, such as SMPS 10, may be covered in insulating material. As noted above, wireless coupling between conductive structure 46 and a switching device can produce a transient response in conductive structure 46. For example, changes in energy in the switching device caused by PWM signal switching may manifest as a transient response in conductive structure 46. The transient response may be or include current produced in conductive structure 46. This current may have a value, such as a magnitude, that is proportional to, or a function of, to the change in energy in the switching device.

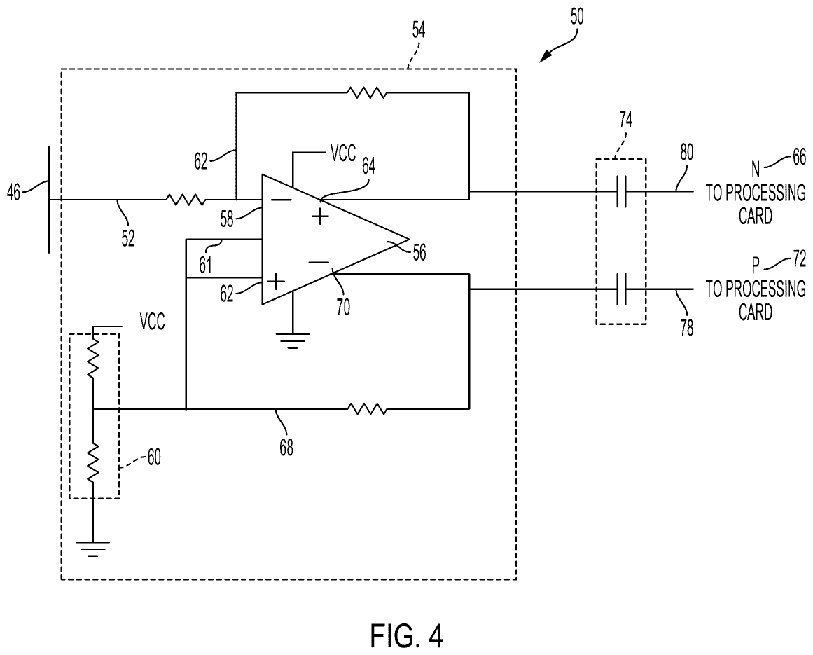

Sensor card 38 may include a printed circuit board (PCB) 48 which includes circuitry, referred to herein as first circuitry, configured to convert the transient response into an electrical signal. FIG. 4 shows an example of first circuitry 50 that may be included in sensor card 38. First circuitry 50 includes a conductor, such as a conductive trace 52, connected to conductive structure 46 on the sensor card to receive a single-ended signal that is, or that is based on, the transient response.

First circuitry 50 is or includes a converter circuit 54 configured to convert this single-ended signal into a differential signal and to amplify the differential signal for output over two or more conductors to the processing card. In this regard, an example differential signal transmits information using two complementary signals, which are two signals that are 180° out of phase of each other. Although a differential signal contains two component signals, a differential signal is referred to herein as “an electrical signal” in accordance with convention, since the two signals taken together are used to transmit a single block of information.

Converter circuit 54 includes a fully operational amplifier (op-amp) 56 that is (i) configured to receive the single-ended signal from conductive structure 46 over conductive trace 52 at its negative input 58 and (ii) electrically connected to a voltage divider 60 at its positive input 62. Output 64 of op-amp 56 is electrically connected to a feedback loop 62 which produces an inverted or negative (N) signal 66, and output 70 of op-amp 56 is electrically connected to a feedback loop 68 which produces a non-inverted or positive (P) signal 72. Connection 61 is a high-impedance common mode voltage connection. The positive (P) signal and negative (N) signal constitute the two components of a differential signal that contains the same information as the single-ended signal received from conductive structure 46. Capacitors 74 are included at the signals outputs 78, 80 to AC-couple the signal back to the processing card. Capacitors 74 may each have a value of 100 nanoFarads (nF); although other values may be used. Since the conductive structure already removes bias information and the goal is to reconstruct the PWM content, the AC-coupling capacitors allow re-biasing of the signal on the processing card. These capacitors can be either on the processing card or on the sensor card. Some implementations do not include the AC coupling capacitors. They may be used in some implementation to simplify processing. Capacitors 74 may be considered part of converter circuit 54 in some implementations.

Converter circuit 54 also amplifies the differential signal by introducing a gain of one-half in this example (e.g., a gain of 50% over the original signal). The gain may be chosen based on the expected coupled energy and the saturation voltages of op-amp circuit 56. If the expected coupled energy is weak, a larger gain may be used. The coupled energy is, in part, related to the voltage swing and the rise and fall times of the voltage swing of device the to which the conductive structure is capacitively coupled—in an example, the input swing of inductor 20. For example if the PWM input to the inductor has a 12V swing and a 5 ns (nanosecond) rise time, more energy would be coupled than a 12V swing with a 10 ns rise time. Another example would be that a 10V swing with a 5 ns rise time would couple more energy than a 5V swing with the same rise time. Use of a differential signal and application of the gain can be beneficial for signal fidelity and isolation from other noise sources. Since many sensor cards may have cables in close proximity to each other, a differential signal may help mitigate potential crosstalk from other sources. Furthermore, the differential signals may help reject common mode errors and the symmetry of the signals may allow for more options when reconstructing the PWM signal to produce the local PWM signal.

Sensor card 38 may be part of a test system including many test channels. The wiring from the sensor card to the processing card may be shielded to limit coupling between channels. Differential signaling helps in this environment. The differential signaling also helps reject any common mode errors or drift in the original single-ended signal. The differential signal and gain thus may enable more accurate transmission of information than its single-ended counterpart.

In another implementation (not shown), converter circuit 54 may include two op-amps including a noninverting op-amp and an inverting op-amp. The single-ended signal from conductive trace 52 passes to the noninverting op-amp and to the inverting op-amp which produce a differential signal based on the single-ended signal from conductive trace 52. The op-amps may provide the gain described above.

Referring back to FIG. 3, sensor card 38 may also include, or connect to, multiple spring-loaded pins 76, such as pogo pins, that are compressible to change the distance between sensor card 38 and SMPS 10, that is, the distance between sensor card 38 and the switching device of the DUT. Each pin 76 is electrically connected to the first circuitry 50 at one end of the pin and to a respective wire, such as coaxial cable or shielded twisted pair, at the other end of the pin. In this example, pin 76a is configured to receive power from the processing card. The power is applied to converter circuit 54. Pin 76b is a ground pin that is configured to provide the negative supply for the converter circuit. In this example, the negative supply is shown to be ground, but it can be any other suitable supply voltage less than the positive supply voltage. This supply may be provided from the processing card. Pin 76c is electrically connected to the noninverting (N) output 78 of converter circuit 54. Pin 76d is electrically connected to inverting output (P) of converter circuit 54. The differential signal produce by the converting circuit is thus sent to processing card 40 via the wires connected to pins 76c and 76d. In some implementations, there may be fewer than four pins and corresponding wires. For example, in some implementations, there may be two spring-loaded pins—one for power and one for ground. The differential signal may be sent over the power pins.

Referring to FIG. 2, sensor card 38 may be remote from processing card 40. As noted above, the two may be separated by wires 82—for example, the shielded twisted pairs and/or coaxial cable described above—each of which may be between 30 centimeters (cm) and 90 cm long. Shorter distances reduce the chances of capacitive coupling and interference from the SMPS occurring in processing card 40. Shorter distances may allow for better signal fidelity.

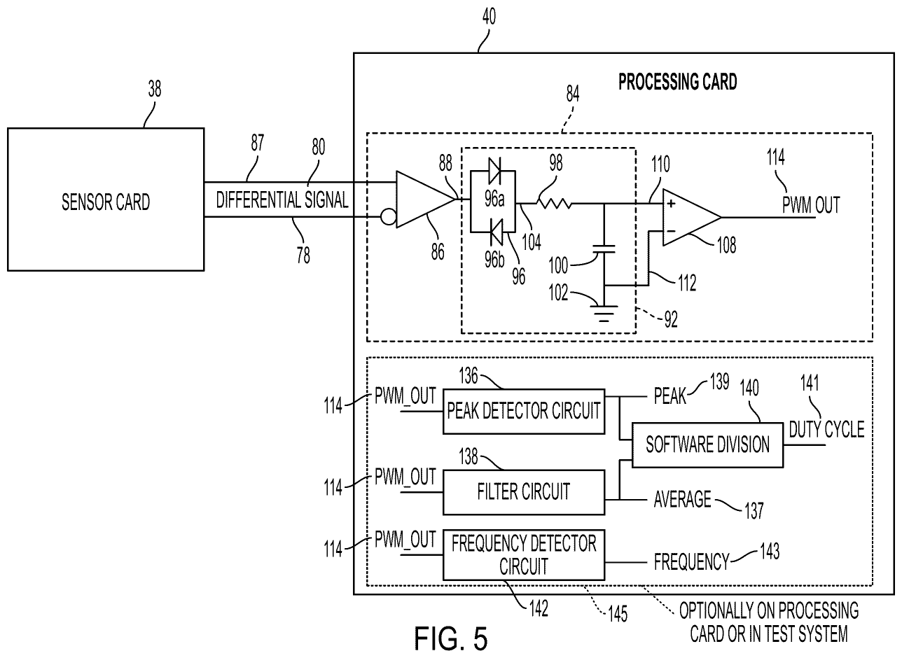

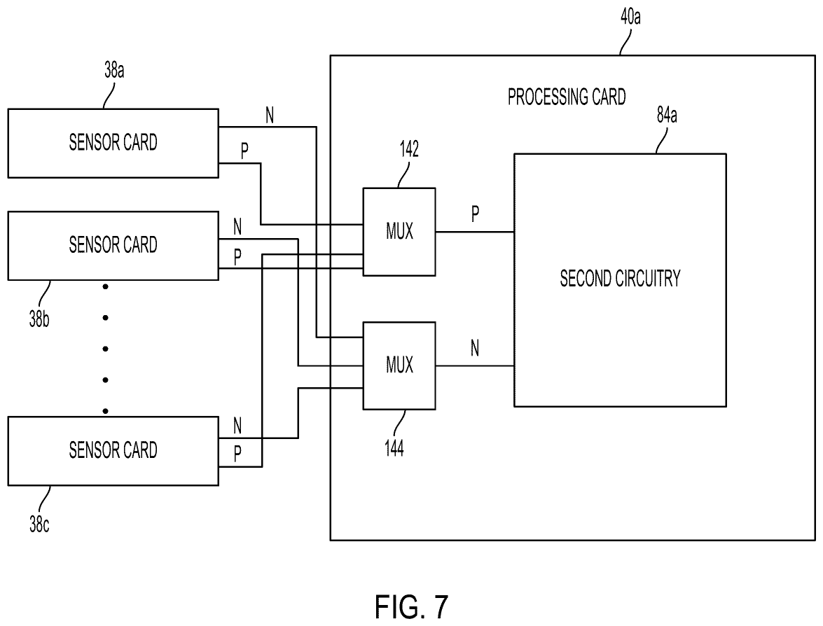

FIG. 5 shows an example implementation of second circuitry 84 on processing card 40. The processing card and second circuitry 84 of FIG. 5 omits multiplexers (“mux”), which may be part of the processing card and second circuitry 84 in some implementations, such as those described with respect to FIGS. 7, 8, and 9 below.

In this example, second circuitry 84 includes a converter circuit 86 that is configured to convert a received differential signal 87 from sensor card 38 over lines 78, 80 to a single-ended electrical signal, which is provided at its output 88. Lines 78 and 80 may be connected to electrical ground using, e.g., 5002, or other value resistors, which are not shown in FIG. 5. The differential signal 87 between the sensor card and the processing card may be AC-coupled and biased by these connections to ground allowing the comparator to work using a ground threshold. Converter circuit 86 may be or include an amplifier that receives the differential signal, that performs the conversion, and that amplifies the resulting single-ended electrical signal by introducing a gain such as a gain of twenty. Other appropriate gains may be used depending on the saturation voltage of the amplifier and the expected input signal amplitude. The gain may be sufficiently large to pass an edge through a subsequent filter circuit to create a signal having a great enough magnitude to process using standard devices. The resulting signal at output 88 is referred to as the amplified electrical signal.

Second circuitry 84 also includes a filter circuit 92. Filter circuit 92 receives the amplified electrical signal from converter circuit 86 and outputs a filtered signal, which is also referred to herein as an intermediate signal. The local PWM signal generated by second circuitry 84 is based on this filtered signal.

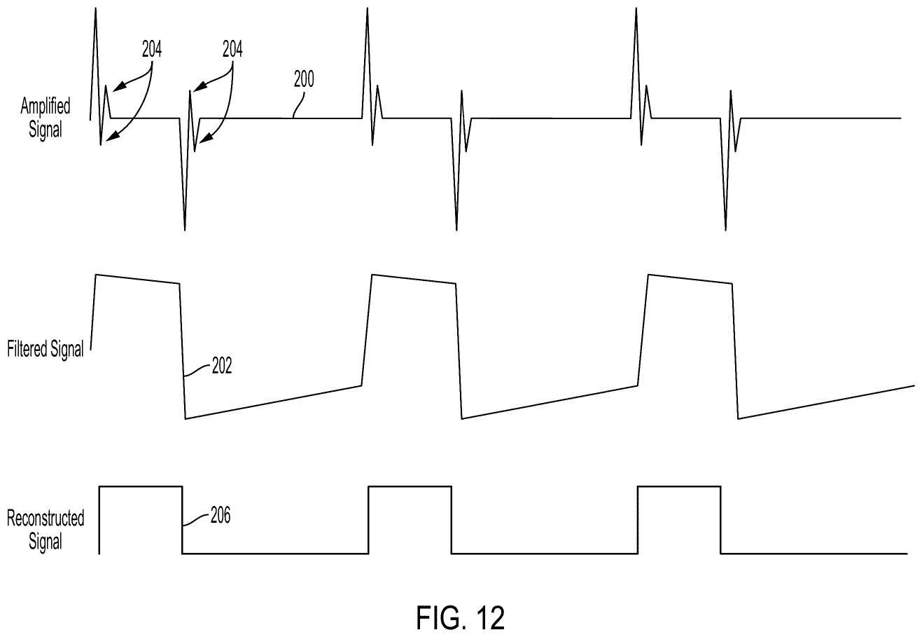

In this example, the filter structure includes hysteresis using two diodes and a capacitor (e.g., a 1 nF (nanoFarad) capacitor) to store energy from a last signal edge transition. A small resistor (e.g., a 10Ω (ohm) resistor) may be added in series to reduce the capacitive load seen by amplifier 86. Since there may be ringing and noise coupled from the PWM source, the filter is configured to capture the intended edges of the PWM source while ignoring the ringing and noise (labeled 204 in FIG. 12 described below). The diodes may require edges to be larger than a diode drop before a transition is recognized and the capacitor temporarily holds the voltage to approximately the state of the last transition. Ringing and noise on the signal due to the transition may be ignored using this architecture, as noted.

In the example shown in the figure, filter circuit 92 includes diodes 96 connected in parallel in opposite directions, a resistor 98 (e.g., 100), and a capacitor 100 (e.g., 1 nF) electrically connected to ground 102. In operation, filter circuit 92 receives the amplified electrical signal from converter circuit 86. Diodes 96 and capacitor 100 are configured to provide a voltage hysteresis of the diode voltage drop. In this regard, capacitor 100 is configured to store a voltage representing a present state (e.g., high or low voltage) of the electrical signal at the output of diodes 96. More specifically, when the voltage output 88 is above the voltage 104 at the output of diodes 96, diode 96a conducts and diode 96b does not conduct, causing capacitor 100 to charge to a voltage representing a present state (e.g., a high voltage state) of the electrical signal at voltage output 88 and to remain at about that state. When the voltage output 88 goes below voltage output 104, diode 96b conducts and diode 96a does not conduct, causing capacitor 100 to discharge and to store a voltage representing the present state (e.g., a low voltage state at voltage output 88) until the voltage output 104 goes above voltage output 88. As noted, resistor 98 may be relatively small and its primary purpose is to reduce instabilities in converter circuit 86 to drive capacitor 100. As noted, capacitor 100 should be large enough to hold the voltage above ground 102 of comparator circuit 108 until a next transition of the electrical signal occurs. The filtered signal in this example is the voltage across capacitor 100 provided to input 110 of comparator circuit 108.

Comparator circuit 108 receives the filtered signal at input 110 and compares the filtered signal to a predefined threshold voltage 112. Comparator circuit 108 generates and outputs the local PWM signal 114 (PWM_OUT) based on the comparison. The local PWM signal corresponds to, but need not be identical to, the PWM signal (e.g., PWM signal 30) used in the DUT (e.g., SMPS 20). For example, the local PWM signal may have a same, or substantially same, duty cycle, frequency, and pulse widths as the PWM signal used in SMPS 10. The local PWM signal may have an amplitude determined by the output swing of comparator 108.

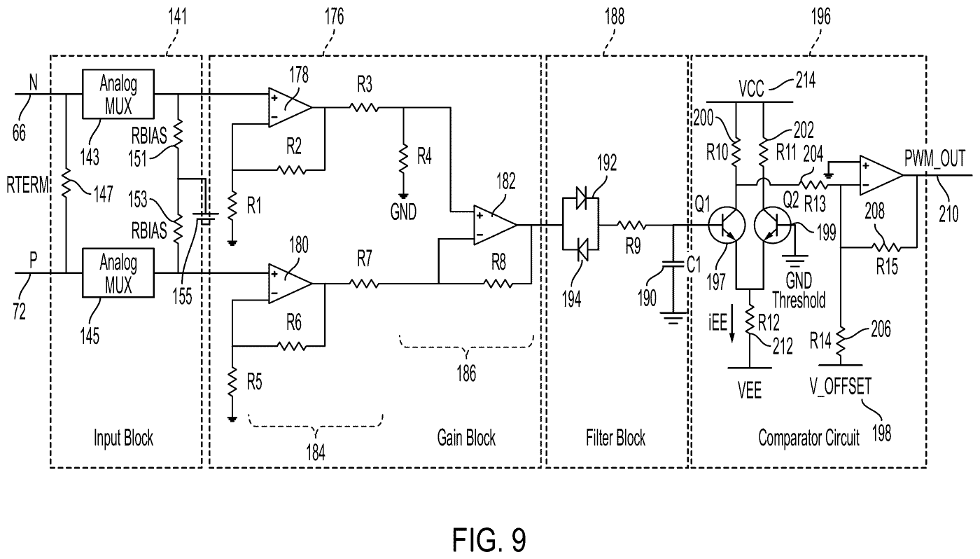

A comparator circuit with hysteresis applied to the amplified filtered signal may be an alternative circuit for reconstructing the PWM signal. A potential issue with using this technique without the filter is that it depends heavily on symmetry of the rising and falling edge transient behavior being similar to set the appropriate comparator hysteresis. If the hysteresis is set too high, then, potentially, some transitions may be missed and if it is too low, then false transitions may be captured. Two comparators with set or programable thresholds to ignore the ringing may, potentially, have the same issue since the waveform ringing is unknown and may vary from device to device. The hysteresis in filter block shown in FIG. 9 significantly removes ringing and provides a clean transition in which to capture the moment as a valid transition.

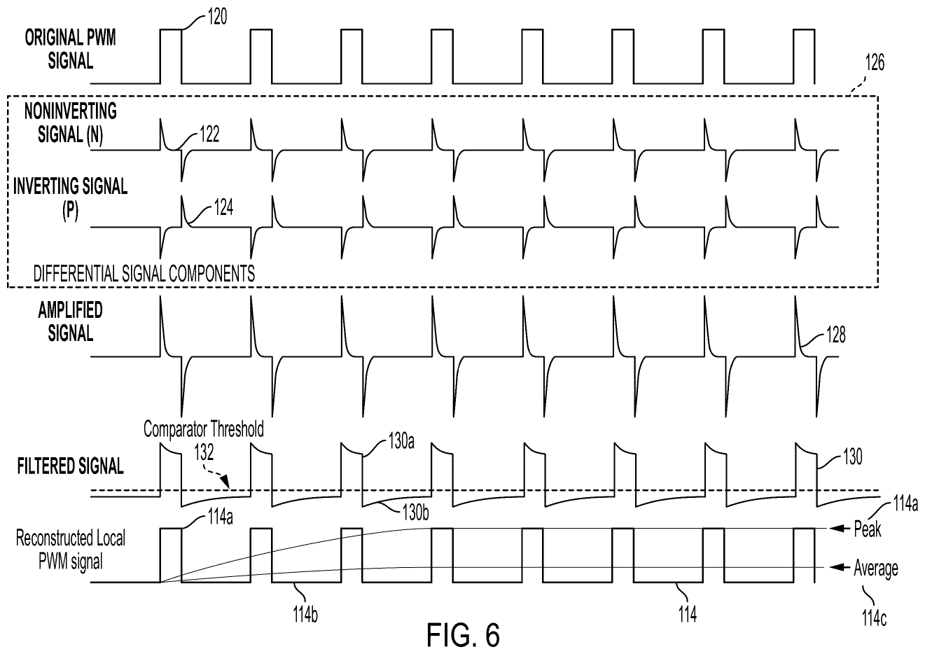

FIG. 6 shows examples of signals produced by the circuitry described herein. The original PWM signal 120 is an example of PWM signal 30 of FIG. 1 that is used to drive switching to produce changes in energy in a switching device. Noninverting signal (N) 122 and inverting signal (P) 124 are example differential signal devices 126 produced by converter circuit 54 and output by sensor card 38 to processing card 40.

Amplified signal 128 is the single-ended, amplified signal that is provided at the output 88 of converter circuit 86 of processing card 40. Filtered signal 130 is the voltage across capacitor 110 that is provided by filter circuit 92 to the input 110 of comparator circuit 110. As shown, when diode 96a conducts and diode 96b does not conduct, capacitor charges to, and substantially maintains, a high voltage 130a as described above until diode 96a stops conducting and diode 96b conducts. When diode 96b conducts and diode 96a does not conduct, capacitor 110 discharges to, and substantially maintains, a low voltage 130b as described above until diode 96b stops conducting and diode 96a conducts, whereafter the process repeats. The decay profile of the voltage across the capacitor may be determined, at least in part, by the loading of the comparator circuit on that node. In the filtered signal, the decay waveform may be dependent on the loading presented by the comparator circuit.

FIG. 12 shows an other example of an amplified signal 200, which is the single-ended, amplified signal that is provided at the output 88 of converter circuit 86 of processing card 40. Filtered signal 202 is the voltage across capacitor 110 that is provided by filter circuit 92 to the input 110 of comparator circuit 110. Filter circuit 92 removes noise 204 when generating filtered signal 202.

Referring back to FIG. 6, the predefined threshold voltage 132 of comparator circuit 108 is also shown. Comparison, by comparator circuit 108, of filtered signal 130 to this threshold voltage 132 produces reconstructed local PWM signal 114. In this example, when a portion of signal 130 is above threshold 132, comparator circuit 108 outputs a high, or peak, voltage 114a. In this example, when a portion of signal 130 is below threshold 132, comparator circuit 108 outputs a low voltage 114b. The amplitude of the local PWM signal may be determined based on the output of the comparator circuit. The comparator circuit may include an amplifier circuit that presents a desired offset and gain to be sent to the test system. The peak-to-peak voltage or amplitude and relative average voltage 114 of local PWM signal 114, among other attributes of local PWM signal 114, may be determined using circuitry described below.

FIG. 12 shows another example of a reconstructed local PWM signal 206 that may be generated as described above based on filtered signal 202.

Referring back to FIG. 5, example processing card 40 may optionally include one or more circuits 145 to determine attributes of the local PWM signal 114. In some implementations, one or more of these circuits may be part of second circuitry 84 In some implementations, one or more of these circuits may not be part of second circuitry 84. In some implementations, one or more of these circuits may be external to processing card 84—for example, part of a test system such as test system 42 (FIG. 2). These attributes of the local PWM signal correspond to, e.g., are or are based on, the attributes of the original PWM signal 30. The attributes may include, but are not limited to, one or more of a relative average voltage of the local PWM signal, a peak-to-peak voltage or amplitude of the local PWM signal, an average duty cycle of the local PWM signal, or a frequency of the local PWM signal.

The peak-to-peak voltage or amplitude, relative average voltage, and/or the local PWM signal may be sent from the processing card to test system 42. The test system may have an on board voltage meter or analog-to-digital converter (ADC) to measure the peak-to-peak voltage or amplitude, relative average voltage using the local PWM signal. The test system also may include a type of time measurement device or circuit to receive the local PWM signal. The time measurement device or circuit may be configured to determine the frequency and/or pulse width information of the local PWM signal. Software processing may be performed using information measured by the test system.

In some implementations, processing card 40 or test system 42 may include a peak detector circuit 136 configured to receive the local PWM signal and to determine a value of a peak-to-peak voltage or amplitude 139 of the local PWM signal. Processing card 40 or test system 42 may include a second filter circuit 138 (e.g., a lowpass filter) configured to receive the local PWM signal and to determine a filtered signal, which may be or correspond to value of an average 137 voltage of the local PWM signal. Software executing either on processing card 40 or on test system 42 may be configured to receive the value of the relative average voltage of the local PWM signal and the value of the peak-to-peak voltage or amplitude of the local PWM signal and to determine, e.g., through division 140, a value of an average duty cycle 141 of the local PWM signal. An average duty cycle of the PWM signal used in the switched-mode power supply is based on the peak-to-peak voltage or amplitude of the local PWM signal and the relative average voltage of the local PWM signal, e.g., relative average divided by peak-to-peak voltage or amplitude. Offset and gain correction may be performed before the division takes place. Processing card 40 or test system 42 may include a frequency detector circuit 142, such as a counter circuit, to count a number of pulses in the local PWM signal over a period of time and, based on the count, determine a frequency 143 of the local PWM signal. Processing card 40 or test system 42 may include a power detector circuit to detect a power of the local PWM signal. If the attributes are determined in processing card 40, the attributes may be sent to test system 42 (FIG. 3) for evaluation and/or further processing. For example, the processing card may generate one or more attribute signals that are then passed to the test system. The test system may use one or more of these signals to determine if a DUT test passes or fails testing.

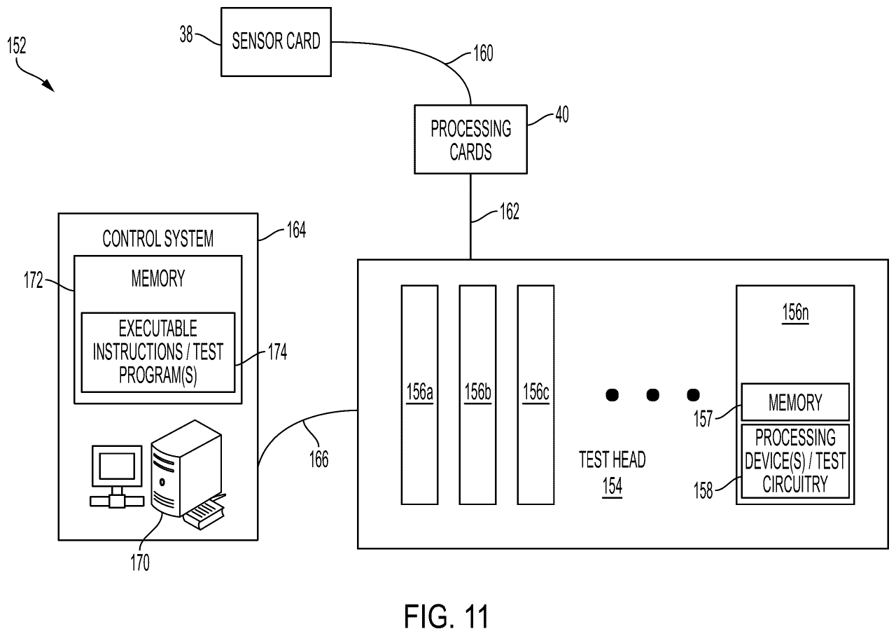

In some implementations, second circuitry 84 does not include circuits of the type described above to determine attributes of the local PWM signal. Instead, processing card 40 sends the local PWM signal to test system 42. Circuitry in test system 42 is configured to determine the attributes of the local PWM signal. The circuitry may be part of a control system of the test system or part of a device of the test system, such as a test instrument. In some implementations, a signal processing device, such as a time measurement device or circuit, that is part of, or associated with, the test system may determine the attributes. For example, the local PWM signal can be used by the test system to determine the clock frequency and duty cycle if the test system's measurement system has sufficient resolution. The peak and averaged voltages can be sent to the test system's internal meter if there is not sufficient resolution in the time measurement system to extract the pulse width or duty cycle of the signal. An example of a test system that may determine the attributes is described with respect to FIG. 11.

FIG. 7 shows an example implementation of a system for testing multiple DUTs, such as SMPSs. In this example, there are multiple instances 38a to 38c of sensor card 38, each of which is configured to wirelessly couple to a switching device of a different DUT. Although only three instances of sensor card 38 are shown, this implementation may contain any number of sensor cards, e.g., more than or fewer than three. Each instance of the sensor card may have the same structure and function as sensor card 38 shown in, and described with respect to, FIGS. 1 to 6, and variants thereof. Processing card 40a may be a variant of processing card 40 described herein in that it may include multiplexer circuitry comprised of a pair of multiplexers 142, 144, and an instance 84a of second processing circuitry 84. The instance 84a of second processing circuitry 84 may have the same structure and function as second processing circuitry 84 shown in, and described with respect to, FIGS. 2 to 6 and 9 below, and variants thereof. The pair of multiplexers 142, 144 may be controlled based on a control signal provided by a controller to select a differential signal from one of sensor cards 38a to 38c. For example, the control signal may select which of the SMPSs data is to be read and output to second processing circuitry 84a. Because the signals from the sensor cards are differential signals, there may be one multiplexer 142 dedicated to selecting a device P signal and one multiplexer 144 dedicated to selecting a device N signal.

These multiplexers may operate using the same control signal. For example, if a control signal selects sensor card 38a, the corresponding P and N signals from multiplexers 142, 144 are output to converter 86 (See FIG. 5) in second circuitry 84a. Thereafter, processing of the P and N devices from sensor card 38a proceed as described above with respect to FIGS. 5 and 6.

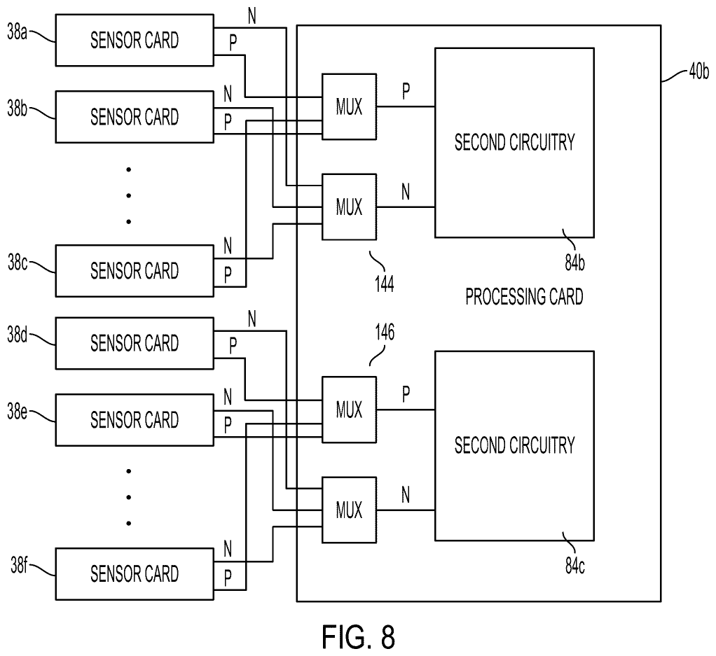

FIG. 8 shows another example implementation of a system for testing multiple DUTs. In this example, there are multiple instances 38a to 38f of sensor card 38, each of which is configured to wirelessly couple to an switching device, such as an inductor, of a different SMPS. Although only six instances of sensor card 38 are shown, this implementation may contain any number of sensor cards, e.g., more than or fewer than six. Each instance of the sensor card may have the same structure and function as sensor card 38 shown in, and described with respect to, FIGS. 1 to 6, and variants thereof. Processing card 40b may be a variant of processing card 40 described herein in that it may include multiple pairs 144, 146 of multiplexers and multiple instance 84b, 84c of second processing circuitry. Although only two pairs of multiplexers are shown, this implementation may contain any number of pairs of multiplexers. Although only two instances of the second circuitry are shown, this implementation may contain any number instances of the second circuitry.

Each instance 84b, 84c of second processing circuitry may have the same structure and function as second processing circuitry shown in, and described with respect to, FIGS. 2 to 6 and 9, and variants thereof. Different pairs of multiplexers may be controlled based on different control signal provided by test system 42 to select the differential signal from different sensor cards for output to a corresponding instance of the second circuitry. Essentially, the implementation of FIG. 8 is a scaled-up version of the implementation of FIG. 7. That is, there are a greater number of multiplexers and instances of second processing circuitry 84 in the implementation of FIG. 8 relative to the implementation of FIG. 7, which enable concurrent testing of multiple SMPSs.

FIG. 9 is a circuit diagram showing an example configuration of a processing card described herein containing multiplexers. FIG. 9 shows input block 141 configured to receive N 66 and P 72 signals from sensor card 38. Input block 141 terminates the signals using resistor 147 (RTERM), selects the signals using analog multiplexers (“analog MUX”) 143 and 145, and biases the signals using resistors 151 and 153 (RBIAS) electrically connected to ground 155.

Gain block 176 is configured to buffer and to amplify the differential outputs of input block 141. Amplifiers 178, 180 buffer and amplify the P and N components of the differential signal. Amplifier 182 amplifies the difference between the P and N components of the differential signal to produce a single-ended output signal to pass to filter block 188. This implementation of the gain block includes two stages 184, 186 so that a high impedance can be presented to the output of each analog multiplexer 143, 145. Some implementations may use a gain of two for first stage 184 and a gain of ten 186 for the next stage. Other combinations of gains can be used.

Filter block 188 includes capacitor 190. Capacitor 190 holds a current voltage state above the threshold of comparator circuit 196 until significant energy is provided from gain block 176 to both activate an opposing diode 192, 194 and change the potential across capacitor 190 to a value that would toggle the output of comparator circuit 196. That value in this example is ground. Capacitor 190 may be sized to support slow discharge due to leakage currents from comparator circuit 196.

Comparator circuit 196 includes a voltage offset V_Offset (−VCC) 198, a resistor 200 (e.g., of 200Ω), a resistor 202 (e.g., of 200Ω), a resistor 204 (e.g., of 800Ω), a resistor 206 (e.g., of 1KΩ), and a resistor 208 (e.g., of 1KΩ). Comparator circuit 196 may be configured to toggle the PWM_Out Pin 210 between and a maximum voltage called VMAX. VMAX may be based on the value of resistor 212 (R12) (e.g., of 5000). The current Iee ˜=(VEE−Vbe)/R12, where Vbe is the base-emitter voltage of transistor 197 or 199. Iee sets the current from VCC 214 into the op-amp circuit defining the output swing. V_Offset 198 sets the offset of the op-amp output which, if −VCC is used, provides a voltage swing between ground and VMAX. If VEE equals −VCC, then VEE can be used for V_OFFSET.

The multiplexers described herein may be or include analog multiplexers. In some implementations, a differential analog multiplexers may be used in place of two single-ended analog multiplexers.

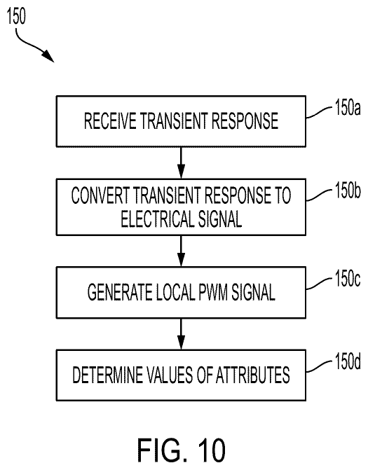

FIG. 10 is a flowchart showing an example process 150 for testing a DUT that includes an switching device. Referring also to FIG. 1, process 150 includes receiving (150a), at a conductive structure 46 wirelessly coupled to the switching device, a transient response that is based on a change in electrical energy in the switching device. For example, as described above with respect to FIG. 1, when switching circuitry 16 is turned on and off by PWM signal 30, the energy stored in inductor 20 of SMPS 10 changes. This changes in energy produces a transient response, e.g., current is induced in, conductive structure 50.

Process 150 includes converting (150b) the transient response into an electrical signal, such as a differential signal. As described above, this conversion may be performed using first circuitry 50 on sensor card 38. Process 150 includes generating (150c) a local PWM signal that corresponds to the PWM signal based on this differential signal. For example, as described with respect to FIGS. 5, 6, 9, and 12 second circuitry 84 on the processing card 40 may generate the local PWM signal as described above by producing an amplified electrical signal based on a differential signal received from the sensor card, by removing at least some noise from the amplified electrical signal to produce a filtered electrical signal, and comparing the filtered electrical signal to a predefined threshold. Process 150 may also include determining (150d) values corresponding to one or more attributes of the local PWM signal. The one or more attributes may be determined as described above and may include one or more of a relative average voltage of the local PWM signal, a peak-to-peak voltage or amplitude of the local PWM signal, an average duty cycle of the local PWM signal, or a frequency of the local PWM signal.

FIG. 11 is a block diagram showing components of example ATE 152 that may be used to implement at least part of the test system described herein, such as test system 42 of FIG. 2.

ATE 152 includes a test head 154, one or more sensor cards 38 of the type described herein, and one or more processing cards 40 of the type described herein. The sensor card(s) 38 are remote from test head 154 and are placeable in proximity to a DUT, such as an SMPS under test so that the conductive structure on the sensor card is within a predefined distance of an switching device. The sensor card(s) may be placed manually or automatically using a robot or robotic gantry, which may be controlled by the control systems described below.

In this example, test head 154 includes test instruments 156a to 156n (where n>3), each of which may be configured, as appropriate, to implement testing and/or other functions. Although only four test instruments are shown, ATE 152 may include any appropriate number of test instruments, including one or more residing outside of test head 154. The test instruments may be hardware devices that each may include memory 157 and one or more processing devices and/or other circuitry 158. The test instruments may be configured—for example, programmed—to receive and to process test signals such as the local PWM signals described herein and/or signals representing values of one or more of the attributes of the local PWM signals. Each test instrument may have a configuration like that of test instrument 156n, which includes one or more processing devices for executing instructions to receive and to process and/or analyze the local PWM signals and/or signals representing values of one or more of the attributes. For example, the one or more processing devices may execute instructions to process the local PWM signals to determine values of the attributes. The one or more processing devices may execute instructions to analyze the local PWM signals and/or signals representing the attributes to determine whether the PWM signal used in an SMPS meets one or more predefined testing standards.

In some implementations, control signals for the multiplexers in the second circuitry may be generated by test program(s) executing on a test instrument.

In some implementations, each processing card, such as processing card 40, may be inside the test head or external to the test head. In some implementations, each processing card, such as processing cards 40, may be part of a test instrument. In some implementations, different processing cards, such as processing card 40, may be parts of different test instruments.

Test channels 160 are configured between each processing card and each sensor card to enable communication between corresponding processing cards and sensor cards. Test channels 162 are configured between each processing card and test head 154 to enable communication between each processing card and the test head. The test channels may be implemented using wiring of the type described herein.

Control system 164 may be configured—e.g., programmed—to communicate with test instruments 156a to 156n to direct and/or to control testing of DUTs, such as, but not limited to, SMPSs. In some implementations, this communication 166 may be over a computer network or via a direct connection such as a computer bus or an optical medium. In some implementations, the computer network may be or include a local area network (LAN) or a wide area network (WAN).

The control system may be or include a computing system comprised of one or more processing devices 170 (e.g., microprocessor(s)) and memory 172 for storing instructions 174 to execute to control operation of the ATE and/or testing, and/or one or more test programs to execute and/or to send to the test instruments for execution. Control system 164 may also be configured to receive local PWM signals and/or signals representing local PWM attributes from the test instrument(s) and to determine whether the corresponding SMPS has passed or failed testing. In some implementations, control signals for the multiplexers in the second circuitry may be generated by test program(s) executing on the control system.

In some implementations, the control functionality of the control system is centralized in processing device(s) 170. In some implementations, all or part of the control functionality attributed to control system 164 may also or instead be implemented on a test instrument and/or all or part of the testing functionality attributed to one or more test instruments may also or instead be implemented on control system 164. For example, the control system may be distributed across processing device(s) 170 and one or more of test instruments 156a to 156n.

All or part of the systems and processes described herein including but not limited to process 150 and its modifications may be configured and/or controlled at least in part by one or more computers using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

As used herein, the terms “comprises,” “comprising,” “includes,” “including,” “has,” “having,” “contains,” “containing,” and any variations thereof, are intended to cover a non-exclusive inclusion, such that systems, techniques, apparatus, structures, processes, or other subject matter described or claimed herein that includes, has, or contains an element or list of elements does not include only those elements but can include other elements not expressly listed or inherent to such systems, techniques, apparatus, structures, processes or other subject matter described or claimed herein.

All examples described herein are non-limiting.

In the description and claims provided herein, the adjectives “first”, “second”, “third”, and the like do not designate priority or order unless context suggests otherwise. Instead, these adjectives may be used solely to differentiate the nouns that they modify.

Any mechanical or electrical connection herein may include a direct physical connection or an indirect physical connection that includes one or more intervening devices unless context suggests otherwise. A connection between two electrically conductive devices includes an electrical connection unless context suggests otherwise. The signals described herein are electrical signals unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A system for testing a switched-mode power supply comprising a device associated with a pulse-width modulated (PWM) signal, the system comprising:
a conductive structure wirelessly coupled to the device such that a change in electrical energy in the device produces a transient response on the conductive structure; and
circuitry configured to perform operations comprising:
converting the transient response into an electrical signal; and
generating, based on the electrical signal, a local PWM signal that corresponds to the PWM signal used in the switched-mode power supply.

2. The system of claim 1, wherein the electrical signal comprises a differential signal.

3. The system of claim 1, further comprising:
devices configured to determine one or more attributes of the local PWM signal, the one or more attributes comprising one or more of a relative average voltage of the local PWM signal, a peak-to-peak voltage or amplitude of the local PWM signal, an average duty cycle of the local PWM signal, power of the local PWM signal, or a frequency of the local PWM signal.

4. The system of claim 1, wherein the circuitry comprises a filter circuit having hysteresis, the local PWM signal being based on an output of the filter circuit.

5. The system of claim 1, wherein the conductive structure comprises a conductive plate at least partly wrapped in an insulating material.

6. The system of claim 1, wherein the local PWM signal comprises a reconstruction of the PWM signal used in the switched-mode power supply, the local PWM signal having a substantially same frequency and substantially same pulse widths as the PWM signal used in the switched-mode power supply.

7. The system of claim 1, wherein the circuitry comprises:
an amplifier circuit configured to receive the electrical signal and to produce an amplified electrical signal based on the received electrical signal;
a filter circuit comprising a charge storage element configured to capture signal transient edges and to remove at least some noise from the amplified electrical signal to produce an intermediate signal having rising and falling edges corresponding to rising and falling edges of the PWM signal; and
a comparator circuit configured to compare the intermediate signal to a predefined reference voltage and to output the local PWM signal.

8. The system of claim 1, wherein the circuitry comprises:
a peak detector circuit configured to receive the local PWM signal and to determine a value of a peak-to-peak voltage or amplitude of the local PWM signal.

9. The system of claim 1, wherein the circuitry comprises:
a filter circuit configured to receive the local PWM signal and to determine a value of a relative average voltage of the local PWM signal.

10. The system of claim 1, further comprising:
a peak detector circuit configured to receive the local PWM signal and to determine a value of a peak-to-peak voltage or amplitude of the local PWM signal; and
a second filter circuit configured to receive the local PWM signal and to determine a value of a relative average voltage of the local PWM signal;
wherein an average duty cycle of the PWM signal used in the switched-mode power supply is based on the peak-to-peak voltage or amplitude of the local PWM signal and the relative average voltage of the local PWM signal.

11. The system of claim 1, wherein the circuitry comprises:
first circuitry configured to perform at least the converting; and
second circuitry configured to perform at least the generating, the second circuitry being remote from the first circuitry.

12. The system of claim 10, further comprising:
two or more conductors between the first circuitry and the second circuitry;
wherein the first circuitry comprise a converter circuit configured to convert a single-ended signal that is based on the transient response into a differential signal for output to the two or more conductors.

13. The system of claim 12, wherein the second circuitry comprises multiplexer circuitry, the multiplexer circuitry being configured to receive the electrical signal over a test channel and to select the electrical signal based on a signal corresponding to the switched-mode power supply.

14. The system of claim 11, wherein the system is configured to test multiple switched-mode power supplies each comprising a respective device associated with a respective PWM signal; and
wherein the system comprises:
multiple instances of the conductive structure each wirelessly coupled to respective devices of different respective switched-mode power supplies; and
multiple instances of the first circuitry each configured to convert a transient response from each respective instance of the conductive structure to a respective electrical signal.

15. The system of claim 14, wherein the second circuitry comprises a pair of multiplexers, the pair of multiplexers being configured to receive a device of each respective electrical signal over a respective test channel and to select a received device of the electrical signal to process in the second circuitry based on a signal corresponding to the switched-mode power supply.

16. The system of claim 14, wherein the system comprises:
multiple instances of the second circuitry that are remote from corresponding instance of the first circuitry and that are each configured to determine, based on a respective electrical signal, values corresponding to one or more attributes of a respective local PWM signal.

17. The system of claim 16, wherein each instance of the second circuitry comprises a pair of multiplexers, each pair of multiplexers being configured to receive respective electrical signals over respective test channels and to select received respective electrical signals to process in the each instance of the second circuitry.

18. The system of claim 1, wherein the local PWM signal is an inverted version of the PWM signal.

19. A method of testing a switched-mode power supply comprising a device associated with a pulse-width modulated (PWM) signal, the method comprising:
receiving, at a conductive structure wirelessly coupled to the device, a transient response that is based on a change in electrical energy in the device;
converting the transient response into an electrical signal; and
generating a local PWM signal that corresponds to the PWM signal used in the switched-mode power supply based on the electrical signal.

20. The method of claim 19, further comprising:
determining values corresponding to one or more attributes of the local PWM signal.

21. The method of claim 20 wherein determining the values corresponding to the one or more attributes of the local PWM signal comprises:
determining a value of a peak-to-peak voltage or amplitude of the local PWM signal.

22. The method of claim 20, wherein determining the values corresponding to the one or more attributes of the local PWM signal comprises:
determining a value of a relative average voltage of the local PWM signal.

23. The method of claim 20, wherein determining the values corresponding to the one or more attributes of the local PWM signal comprises:
determining a value of an average duty cycle of the local PWM signal.

24. The method of claim 20, wherein determining the values corresponding to the one or more attributes of the local PWM signal comprises:
determining a value of a frequency of the local PWM signal.

25. The method of claim 19, wherein the one or more attributes comprise one or more of a relative average voltage of the local PWM signal, a peak-to-peak voltage or amplitude of the local PWM signal, an average duty cycle of the local PWM signal, or a frequency of the local PWM signal.

26. The method of claim 19, wherein generating the local PWM signal comprises:
producing an amplified electrical signal based on the received electrical signal; and
removing at least some noise from the amplified electrical signal to produce an intermediate electrical signal;
wherein the local PWM signal is generated based on the intermediate electrical signal.

27. The method of claim 19, wherein the local PWM signal has a substantially same frequency and duty cycle as the PWM signal used in the switched-mode power supply.

28. The method of claim 19, wherein converting is perform by first circuitry, generating is performed by second circuitry, and the first circuitry is remote from the second circuitry.
